(19) United States
(12) Patent Application Publication
(10) Pub. No.: US 2014/0353023 A1
(43) Pub. Date: Dec. 4, 2014

(54) PRINTED CIRCUIT BOARD

(71) Applicants: Hon Hai Precision Industry Co., Ltd., New Taipei (TW); Hong Fu Jin Precision Industry (ShenZhen) Co., Ltd., Shenzhen (CN)

(72) Inventors: YUN ZHANG, Shenzhen (CN); MIAO HE, Shenzhen (CN)

(21) Appl. No.: 13/929,783

(22) Filed: Jun. 28, 2013

(30) Foreign Application Priority Data
Jun. 4, 2013 (CN) 2013102182599

(51) Int. Cl. H05K 1/11; H05K 1/02

(52) U.S. Cl. CPC H05K 1/111; H05K 1/0298
USPC 174/261

(57) ABSTRACT

A printed circuit board (PCB) includes a board body including a top layer, a bottom layer, and a number of reference layers arranged between the top layer and the bottom layer. First and second pads are arranged on the top layer and connected to signal transmission lines of the top layer. The first and second pads are electrically connected to a pair of differential pins of a quad flat package chip. A clearance hole is defined in the reference layer which is nearest to the top layer and located under the first and second pads. Projections of the first and second pads are located within the clearance hole.

### BACKGROUND

1. Technical Field

The present disclosure relates to a printed circuit board.

2. Description of Related Art

Signal integrity is an important factor to be taken into account when a printed circuit board (PCB) is designed. Proper signal integrity helps the PCB and associated computer system to achieve stable performance In general, some quad flat package (QFP) chips are arranged on the PCB through a plurality of pins. When the characteristic impedances of the pins of the QFP chip do not match with the characteristic impedances of pads on the PCB and associated transmission lines on the PCB, signals from the PCB arriving at the pins of the QFP chip can be partially reflected and cause the signals to distort, overshoot, or undershoot. Thus, the pins of the QFP chip may reduce quality of the signals. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawing, like reference numerals designate corresponding parts throughout the several views.

FIG. 1 is a schematic, front view of a PCB having a clearance hole in accordance with an embodiment of the present disclosure.

FIG. 2 is a sectional view of the PCB of FIG. 1, taken along line II-II and showing multiple layers of the PCB.

FIG. 3 is a schematic, front view of a quad flat package chip mounted on the PCB of FIG. 1.

FIG. 4 is a waveform diagram of the PCB of FIG. 1 and a PCB without a clearance hole.

### DETAILED DESCRIPTION

The disclosure, including the drawings, is illustrated by way of example and not by way of limitation. References to “an” or “one” embodiment in this disclosure are not necessarily to the same embodiment, and such references mean “at least one.”

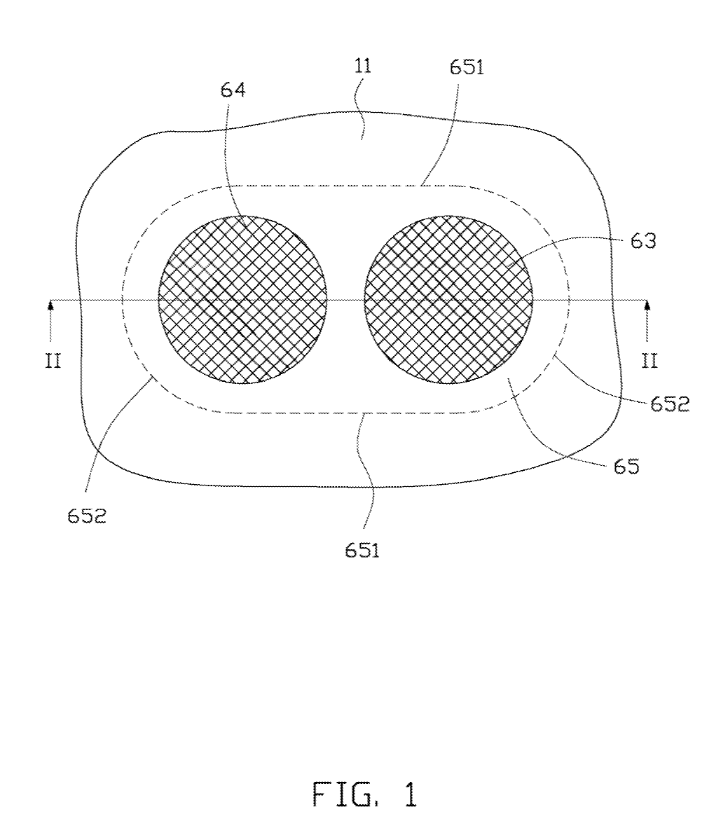

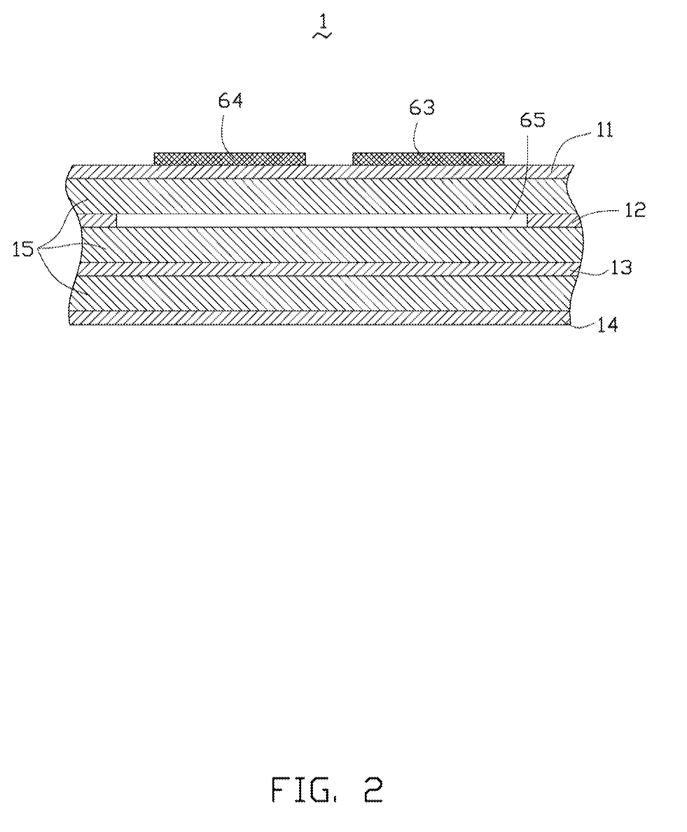

FIGS. 1 and 2 show a printed circuit board (PCB) in accordance with an embodiment includes a board body 1. The board body 1 includes a top layer 11, a bottom layer 14, and a plurality of reference layers interposed between insulating layers 15 arranged between the top layer 11 and the bottom layer 14. In one embodiment, the reference layers include a power layer 12 and a signal layer 13. The top layer 11 is a signal layer. The bottom layer 14 is a ground layer.

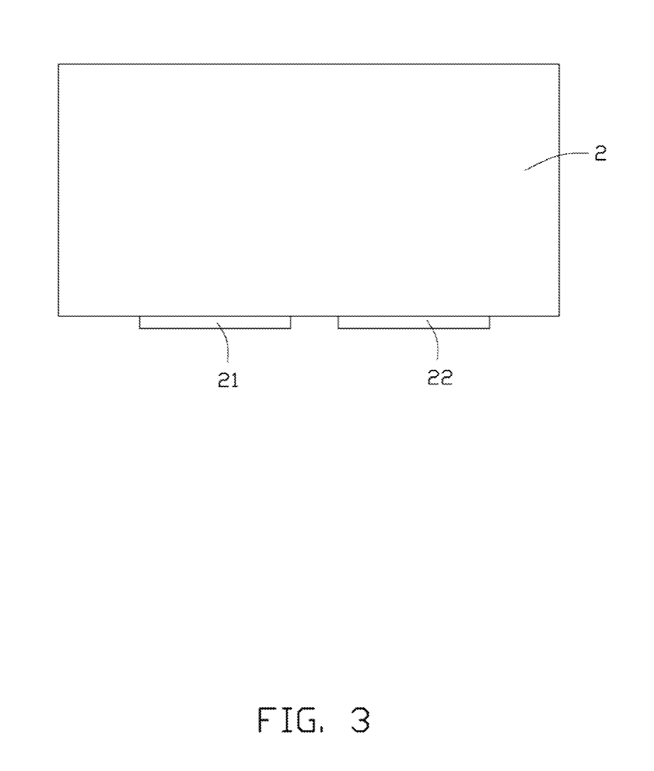

A pair of pads 63 and 64 is arranged on the top layer 11 of the board body 1, to be electrically connected to signal transmission lines of the top layer 11. The pads 63 and 64 are configured to be electrically connected to a pair of differential pins 21 and 22 of a quad flat package (QFP) chip 2 (see FIG. 3), to transmit differential signals between the QFP chip 2 and the board body 1. A clearance hole 65 is defined in the power layer 12 under the pads 63 and 64. Projections of the pads 63 and 64 are located within the clearance hole 65.

In this embodiment, the pads 63 and 64 are circular pads. The clearance hole 65 is oval and has two opposite straight edges 651 parallel to a central line extending through centers of the pads 63 and 64, and two arc-shaped edges 652 each interconnecting with the two straight edges 651. A distance between each of the two opposite straight edges 651 and the central line is same. The two opposite straight edges 651 and the two arc-shaped edges 652 are spaced apart from the pads 63 and 64. Centers of the two arc-shaped edges 652 overlap with centers of the pads 63 and 64. A diameter of each arc-shaped edge 652 is greater than the diameter of each of the pads 63 and 64. A distance between the two opposite straight edges 651 is greater than the diameter of each of the pads 63 and 64. In other embodiments, the clearance holes 65 can be other shapes, such as a circle, an oval, or a rectangle.

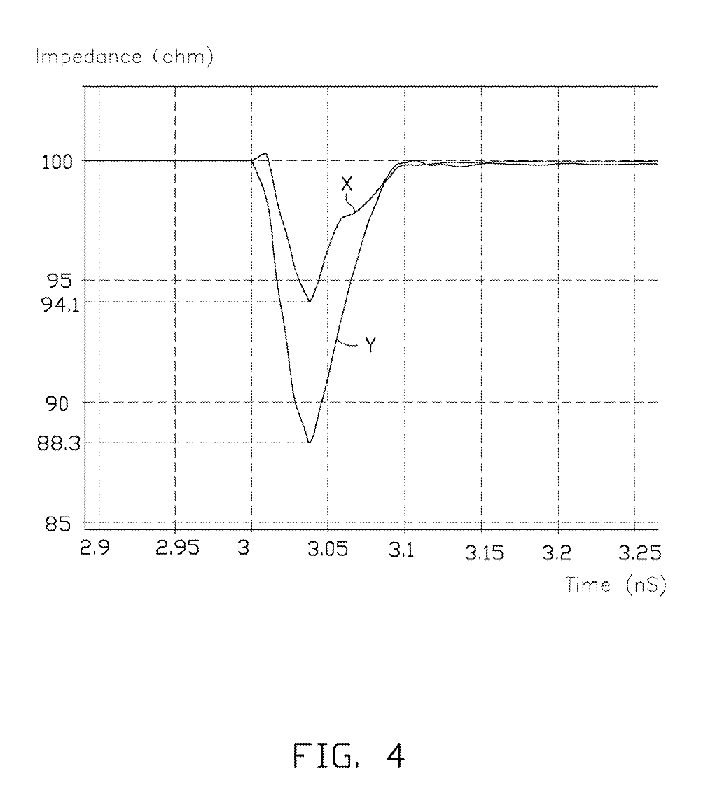

FIG. 4 shows a waveform X of the PCB having the clearance hole 65 and a waveform Y of a PCB without a clearance hole. The maximal impedance of the waveform X and Y is 100 ohm, the minimal impedance of the waveform Y is 88.3 ohm, and the minimal impedance of the line X is 94.1 ohm. Thus, the minimal impedance of the waveform of the PCB with the clearance hole 65 is decreased, and quality of the signals passed by the differential transmission lines is improved.

The PCB matches the characteristic impedances of the differential pins 21 and 22 of the QFP chip 2 with the characteristic impedances of the pads 63, 64 and the differential transmission lines, to improve quality of the signals passed by the differential pins 21 and 22 through the clearance hole 65.

Even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A printed circuit board (PCB) comprising:
a board body comprising:
a top layer;
a bottom layer;
a plurality of reference layers interposed between insulating layers arranged between the top layer and the bottom layer;
a first pad arranged on the top layer and connected to signal transmission lines of the top layer;
a second pad arranged on the top layer and connected to the signal transmission lines of the top layer, wherein the first and second pads are electrically connected to a pair of differential pins of a quad flat package chip; and
a clearance hole defined in the reference layer which is nearest to the top layer and located under the first and second pads, wherein projections of the first and second pads are located within the clearance hole.

2. The PCB of claim 1, wherein the clearance hole is a circle, or an oval, or a rectangle in the front view of the board body.

3. The PCB of claim 1, wherein the clearance hole is oval in the front view of the board body, and the clearance hole has two opposite straight edges parallel to a central line extending through centers of the first and second pads, and two arc-shaped edges each interconnecting the two straight edges, a distance between each of the two opposite straight edges and the central line is same.

4. The PCB of claim 3, wherein the first and the second pads are circular pads, a distance between the two opposite straight edges is greater than a diameter of each of the first and second pads.

5. The PCB of claim 3, wherein the first and the second pads are circular pads, centers of the arc-shaped edges are respectively overlapped with centers of the first and second pads, and a diameter of each of the arc-shaped edges is greater than a diameter of each of the first and second pads.

6. The PCB of claim 1, wherein the top layer is a signal layer and the bottom layer is a ground layer.
